(19) United States
(12) Patent Application Publication
(10) Pub. No.: US 2013/0195587 A1
(43) Pub. Date: Aug. 1, 2013

(54) WAFER TRANSFER DEVICE

(71) Applicants: Hiroki HOSAKA, Nirasaki City (JP); Masahiko AKIYAMA, Nirasaki City (JP)

(72) Inventors: Hiroki HOSAKA, Nirasaki City (JP); Masahiko AKIYAMA, Nirasaki City (JP)

(73) Assignee: TOKYO ELECTRON LIMITED, Tokyo (JP)

(21) Appl. No.: 13/564,259

(22) Filed: Aug. 1, 2012

(30) Foreign Application Priority Data
Aug. 1, 2011 (JP) 2011-168421

(51) Int. Cl. H01L 21/677

(52) U.S. Cl. CPC H01L 21/6773
USPC 414/222.13

(57) ABSTRACT

A wafer transfer device includes: a wafer compartment; a pre-alignment chamber, provided either above or below the wafer compartment; a first wafer transfer chamber, provided in a vertical direction along the wafer compartment and the pre-alignment chamber, for transferring the semiconductor wafer from the wafer compartment to the pre-alignment chamber; and an alignment chamber for aligning the semiconductor wafer, the alignment chamber being provided adjacent to the pre-alignment chamber. The wafer transfer device further includes a second wafer transfer chamber, disposed along an arrangement direction of the first wafer transfer chamber, the pre-alignment chamber and the alignment chamber, for transferring the semiconductor wafer among the pre-alignment chamber, the alignment chamber and the test chambers.

### FIELD OF THE INVENTION

The present invention relates to a wafer transfer device used in a wafer test apparatus for testing electrical characteristics of a semiconductor wafer; and, more particularly, to a wafer transfer device capable of reducing a footprint.

### BACKGROUND OF THE INVENTION

Examples of the wafer test apparatus may include a probe apparatus for performing electrical characteristics test on a plurality of devices, a burn-in test apparatus for performing an accelerated test on the devices, wherein the tests may be performed while the devices are still formed on the wafer, and the like.

A probe apparatus generally includes a loader chamber for transferring a wafer and a test chamber for testing electrical characteristics of the wafer. The electrical characteristics of the wafer are tested by controlling various devices within the loader chamber and the test chamber through a control device. The loader chamber includes a cassette mounting unit for mounting wafers on a cassette basis, a wafer transfer unit for transferring a wafer between a cassette and the test chamber, and a pre-alignment unit for pre-aligning the wafer during the transfer of the wafer by the wafer transfer unit. The test chamber includes a mounting table for mounting thereon the wafer received from the loader chamber and moving the wafer in X, Y, Z and θ directions, a probe card disposed above the mounting table, and an alignment unit for aligning a plurality of probes of the probe card and a plurality of electrodes of the wafer in cooperation with the mounting table. After the mounting table and the alignment unit align the wafer and the probe card in cooperation, the electrical characteristics of the wafer are tested.

In the case of a burn-in test apparatus, as described in Japanese Patent Application Publication No. H11-186349, a plurality of electrodes of a wafer supported by a wafer tray and a plurality of bumps of a probe sheet are aligned, and the wafer tray, the wafer and the probe sheet and the like are assembled as a single card through vacuum adsorption. Then, the card is transferred to be installed in a burn-in unit, and the accelerated wafer test is performed at a predetermined high temperature within the burn-in unit.

However, the conventional probe apparatus has the following problems. For example, in the probe apparatus, the mounting table in the test chamber functions as a wafer transfer unit that moves in X, Y, Z and θ directions during the alignment of the semiconductor wafer. Therefore, the wafer transfer unit in the loader chamber and the mounting table capable of moving in X, Y, Z and θ directions in the test chamber are provided as the wafer transfer device for a single test chamber, and the wafer transfer device occupies a large space. In the case of the conventional probe apparatus, the dedicated space of the wafer transfer device affects the loader chamber and the test chamber. Accordingly, when a plurality of probe apparatuses is installed depending on the production capacity of the device, the footprint of the wafer transfer device is considerably increased and the installation cost is also increased as the number of the probe apparatuses is increased.

### SUMMARY OF THE INVENTION

In view of the above, the present invention provides a wafer transfer device capable of allowing a transfer space of a semiconductor wafer to be shared by a plurality of test chambers and reducing a footprint considerably.

In accordance one aspect of the present invention, there is provided a wafer transfer device for transferring a semiconductor wafer accommodated in a housing to a plurality of test chambers for testing electrical characteristics of the semiconductor wafer, the wafer transfer device including: a wafer compartment for accommodating therein the housing; a pre-alignment chamber, provided either above or below the wafer compartment, for pre-aligning the semiconductor wafer prior to the electrical characteristics test; a first wafer transfer chamber, provided in a vertical direction along the wafer compartment and the pre-alignment chamber, for transferring the semiconductor wafer from the wafer compartment to the pre-alignment chamber; an alignment chamber for aligning the semiconductor wafer, the alignment chamber being provided adjacent to the pre-alignment chamber with the pre-alignment chamber disposed between the alignment chamber and the first wafer transfer chamber; a second wafer transfer chamber, disposed along an arrangement direction of the first wafer transfer chamber, the pre-alignment chamber and the alignment chamber, for transferring the semiconductor wafer among the pre-alignment chamber, the alignment chamber and the test chambers.

Preferably, the wafer transfer device may further include additional wafer compartment, additional pre-alignment chamber, and additional alignment chamber, wherein the wafer compartments, the pre-alignment chambers, the alignment chambers, and the second wafer transfer chamber are horizontally symmetrically arranged with respect to the first wafer transfer chamber.

Preferably, the first wafer transfer chamber may have a first wafer transfer unit for transferring the semiconductor wafer from the wafer compartment to the pre-alignment chamber.

Preferably, the pre-alignment chamber may have a pre-alignment unit for pre-aligning the semiconductor wafer.

Preferably, the second wafer transfer chamber may have a second wafer transfer unit for transferring the semiconductor wafer among the pre-alignment chamber, the alignment chamber and the test chambers.

Preferably, the pre-alignment chamber may have a wafer transport unit for transporting the semiconductor wafer pre-aligned by the pre-alignment unit to the second wafer transfer unit.

Preferably, the second wafer transfer unit may have a supporting plate for supporting the semiconductor wafer to transfer the semiconductor wafer.

In accordance with the present invention, it is possible to provide a wafer transfer device capable of allowing a transfer space of a semiconductor wafer to be shared by a plurality of test chambers and reducing a footprint considerably.

### BRIEF DESCRIPTION OF THE DRAWINGS

FIG. 1 is a top view showing an embodiment of a wafer test apparatus employing a wafer transfer device of the present invention;

FIG. 2 is a front view of the wafer transfer device shown in FIG. 1;

FIG. 3 is a rear view of the wafer transfer device shown in FIG. 1;

FIG. 4 is a perspective view of principal parts of an arm and a wafer transport unit used in a pre-alignment chamber of the wafer transfer device shown in FIG. 1;

FIG. 5 is a perspective view of an arm of a second wafer transfer unit of the wafer transfer device shown in FIG. 1;

FIG. 6 explains relationship between an arm and an alignment unit in an alignment chamber of the wafer transfer device shown in FIG. 1;

FIG. 7 explains relationship between a test chamber adjacent to the wafer transfer device shown in FIG. 1 and a transfer arm;

FIGS. 8A to 8C explain an operation of the wafer transport unit shown in FIG. 4;

FIGS. 9A and 9B show alignment processes in an alignment chamber shown in FIG. 6; and

FIGS. 10A and 10B show alignment processes continued from the processes shown in FIGS. 9A and 9B.

### DETAILED DESCRIPTION OF THE EMBODIMENTS

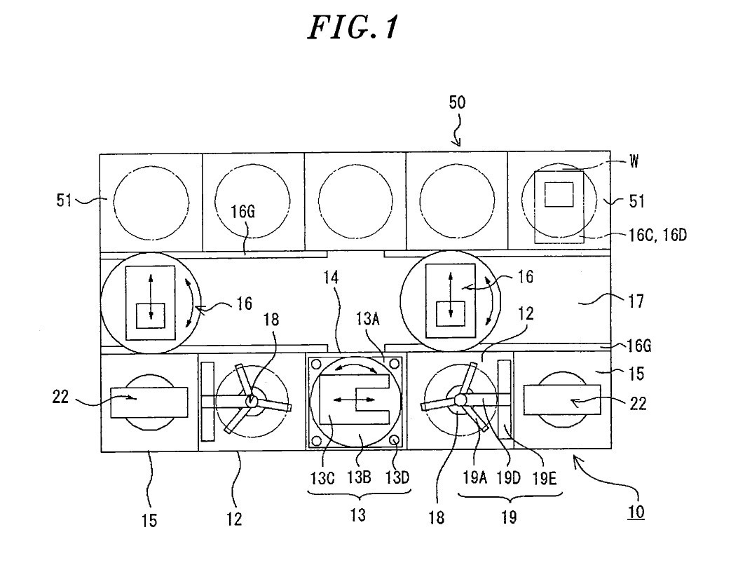

Hereinafter, the present invention will be described based on embodiments shown in FIGS. 1 to 10.

As shown in FIG. 1, a wafer transfer device 10 of the present embodiment is installed along a test area 50 extending in a horizontal direction, and is configured to transfer a semiconductor wafer W between test chambers 51 arranged in multiple rows and stages inside the test area 50. In the test chambers 51, only the electrical characteristics test on an aligned semiconductor wafer W transferred by the wafer transfer device 10 is carried out, and a semiconductor wafer transfer space for alignment is omitted unlike the conventional case.

As shown in FIGS. 1 to 3, the wafer transfer device 10 includes: an upper and a lower wafer compartment 11 for receiving a housing F, e.g., a FOUP (front opening unified pod) or the like, for accommodating therein a plurality of semiconductor wafers; a pre-alignment chamber 12 provided below the wafer compartments 11; a first wafer transfer chamber 14 having a first wafer transfer unit 13 capable of moving vertically along the upper and the lower wafer compartment and the pre-alignment chamber 12; an alignment chamber 15 provided adjacent to the pre-alignment chamber 12 with the pre-alignment chamber 12 disposed between the alignment chamber 15 and the first wafer transfer chamber 14; and a second wafer transfer chamber 17 having a second wafer transfer unit 16 moving along the arrangement direction of the first wafer transfer chamber 14, the pre-alignment chamber 12 and the alignment chamber 15.

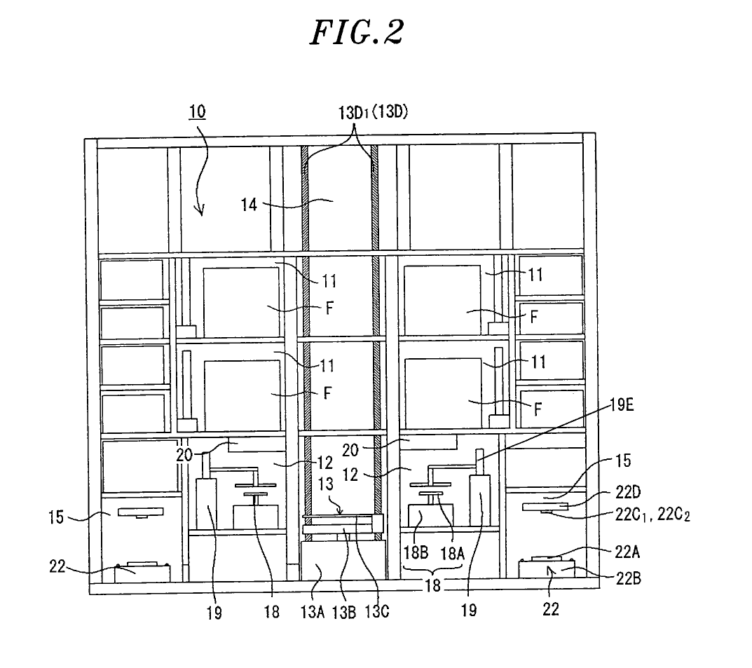

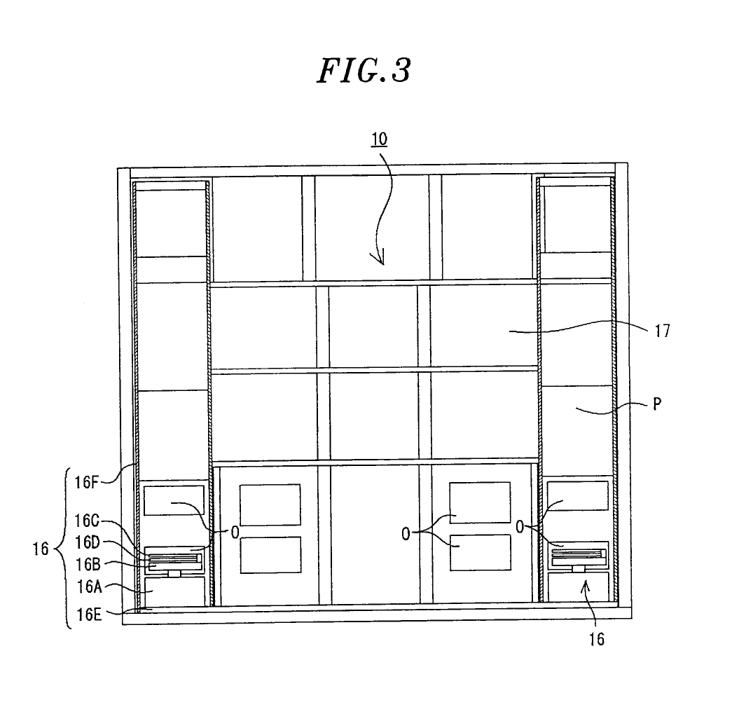

As shown in FIGS. 1 and 2, the upper and the lower wafer compartments 11, the pre-alignment chambers 12 disposed therebelow, and the alignment chambers 15 provided, e.g., at right side thereof are horizontally symmetrical with respect to the first wafer transfer chamber 14. Provided in the second wafer transfer chamber 17 are two second wafer transfer units 16 for transferring the semiconductor wafer between a right chamber and a left chamber. As shown in FIG. 3, the second wafer transfer chamber 17 is partitioned from another chamber by a partition wall P, and an opening O through which the semiconductor wafer is loaded and unloaded is formed at the partition wall P.

An opening/closing unit (not shown) for opening and closing a lid of the housing F is provided at the wafer compartment 11. The lid of the housing F is opened by the opening/closing unit when a semiconductor wafer W is loaded into and unloaded from the housing F by the first wafer transfer unit 13 in the first wafer transfer chamber 14.

As shown in FIG. 2, the pre-alignment chamber 12 includes: a pre-alignment unit 18 for pre-aligning a semiconductor wafer W transferred by the first wafer transfer unit 13; a wafer transport unit 19 for transporting the pre-aligned semiconductor wafer W from the pre-alignment unit 18 to the second wafer transfer unit 16; and a buffer chamber 20 disposed above the wafer transport unit 19. Provided in the buffer chamber 20 are a receiving shelf of a grinding plate for grinding a probe card (not shown) and a receiving shelf for temporarily receiving the semiconductor wafer W.

Hence, as shown in FIG. 2, the first wafer transfer unit 13 has a base 13A, a rotational body 13B capable of rotating forward and backward about a rotation shaft formed on the base 13A, an arm 13C capable of moving reciprocally in one direction on the rotational body 13B, and an elevation unit 13D for vertically moving the base 13A. The first wafer transfer unit 13 is configured to load and unload the semiconductor wafer W into and from the wafer compartment 11 and the pre-alignment chamber 12 by using the arm 13C to which the semiconductor wafer W is vacuum-attracted to be held thereat. The elevation unit 13D has, e.g., ball screws 13D₁ provided along a right and a left inner wall of the first wafer transfer chamber 14, nuts (not shown) fixed to both sides of the base 13A so as to be screw-coupled to the ball screws 13D₁, and a motor (not shown) for rotating the ball screws 13D₁. The elevation unit 13D is configured to vertically move the base 13A and the arm 13C.

As shown in FIG. 2, the pre-alignment unit 18 provided in the pre-alignment chamber 12 has a sub-chuck 18A for vacuum-attracting and forwardly and backwardly rotating the semiconductor wafer W transferred by the first wafer transfer unit 13, a base 18B having therein a driving unit for forwardly and backwardly rotating the sub-chuck 18A, and a sensor (not shown) for detecting a mark, e.g., an orientation flat or a notch of the semiconductor wafer W rotated by the sub-chuck 18A. The pre-alignment unit 18 is configured in such a manner that the mark of the semiconductor wafer W is sensed by the sensor while the semiconductor wafer W is being rotated by the sub-chuck 18A and the semiconductor wafer W is stopped in a predetermined orientation by the sub-chuck 18A.

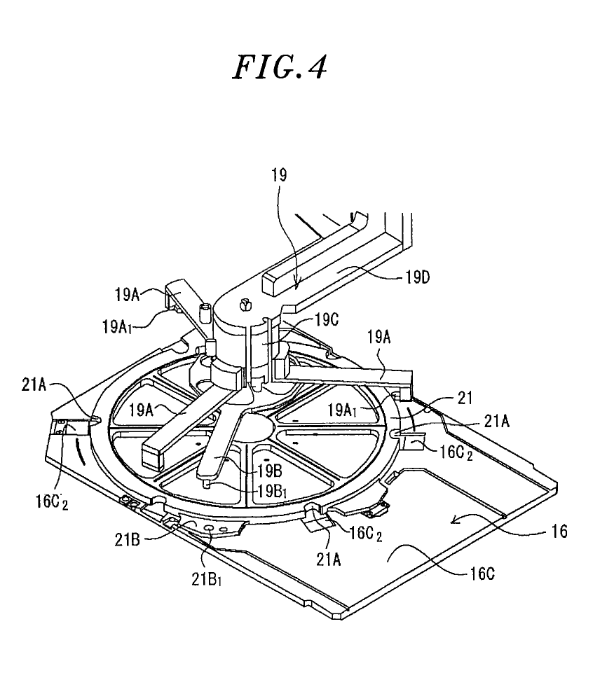

As shown in FIGS. 2 and 4, the wafer transport unit 19 disposed in the pre-alignment chamber 12 includes: radially extending three grip rods 19A arranged to be spaced apart from each other at an interval of about 120° in the circumferential direction, for gripping the semiconductor wafer; two positioning rods 19B arranged to be spaced apart at an interval of about 180° in the circumferential direction below the three grip rods 19A; a driving body 19C coupled to both components and having therein an extensible and contractible device for extending and contracting the three grip rods 19A; an arm 19D for supporting the driving body 19C at a leading end portion thereof; and a support body 19E (see FIG. 2) for horizontally supporting the arm 19D while allowing vertical movement of the arm 19D. The wafer transport unit 19 is configured in such a manner that the three grip rods 19A are extended to grip the pre-aligned semiconductor wafer and lowered to transport the semiconductor wafer to the second wafer transfer unit 16 shown in FIG. 4. Further, support portions 19A₁, each having an ‘L’ shape folded inward, are provided at the leading end portions of the grip rods 19A to support the outer peripheral portion of the semiconductor wafer. The support portions 19A₁ support the outer peripheral portion of the semiconductor wafer by vacuum attraction. Therefore, the wafer transport unit 19 adsorbs and horizontally grips the semiconductor wafer by using the support portions 19A₁ formed at the leading end portions of the three grip rods 19A. In that state, the wafer transport unit 19 can be vertically moved by the arm 19D. Further, pins 19B₁ are provided to be extended downward from the leading ends of the two positioning rods 19B, and the alignment is performed with respect to the second wafer transfer unit 13 by the pins 19B₁.

As shown in FIGS. 1, 3 and 4, the second wafer transfer unit 16 has a base 16A, a rotational body 16B capable of rotating forwardly and backwardly about a rotational shaft formed on the base 16A; an upper and a lower arm 16C and 16D capable of reciprocally moving in one direction on the rotational body 16B; a moving unit 16E for reciprocally moving the base 16A and the arms 16C and 16D in the arrangement direction of the pre-alignment chamber 12 and the alignment chamber 15; and an elevation unit 16F for vertically moving the base 16A and the arms 16C and 16D. The second wafer transfer unit 16 is configured in such a manner that the base 16A and the arms 16C and 16D load and unload the semiconductor wafer W into and from the pre-alignment chamber 12 and the alignment chamber 15. The moving unit 16E has ball screws disposed at both end portions of the bottom surface of the second wafer transfer chamber 17 and is configured to move the base 16A and the arms 16C and 16D in a horizontal direction along the rail 16G. The moving unit 16E moves the base 16A and the arm 16C in a vertical direction as in the elevation unit 13D of the first wafer transfer unit 13.

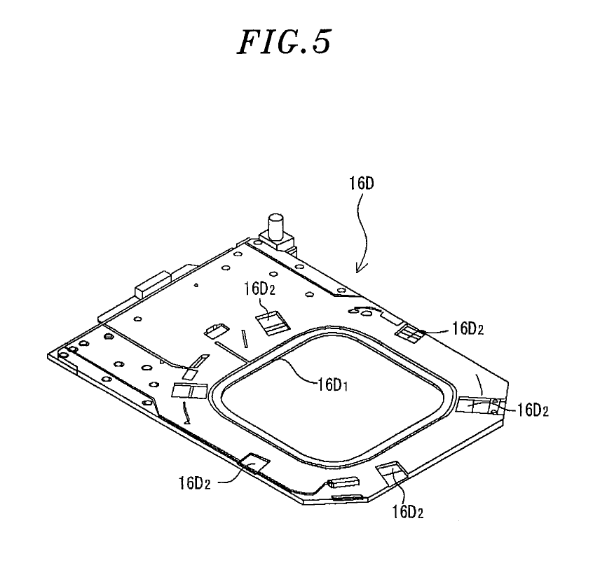

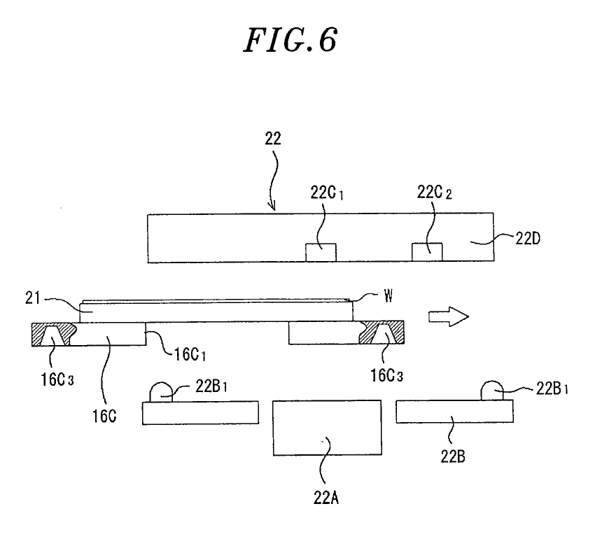

As shown in FIGS. 4 and 5, the upper arm 16C has substantially rectangular shape for transferring an untested semiconductor wafer W and the lower arm 16D has a substantially rectangular shape for transferring a tested semiconductor wafer. As shown in FIG. 4, the upper arm 16C adsorptively attracts the pre-aligned semiconductor wafer W via the wafer supporting plate 21 in the pre-alignment chamber 12 and transfers the adsorptively attracted semiconductor wafer W to the alignment chamber 15. When the wafer supporting plate 21 is removed from the upper arm 16C, the upper arm 16C has substantially the same shape as that of the lower arm 16D shown in FIG. 5. As in the lower arm 16D shown in FIG. 5, a large rectangular opening 16C₁ (see FIG. 6) is formed from the central portion to the leading end portion of the upper arm 16C. Since the upper and the lower arm 16C and 16D have substantially the same shape, the reference numerals used for the upper arm 16C are also used for the lower arm 16D shown in FIG. 5.

As shown in FIG. 4, the wafer supporting plate 21 has substantially the same outer diameter as that of the semiconductor wafer W. Cutout portions 21A are formed at six locations of the outer peripheral portion of the wafer supporting plate 21 spaced with a regular interval. Among them, three cutout portions 21A are arranged to allow the support portions 19A₁ of the three support rods 19A for supporting the semiconductor wafer W to pass therethrough. Moreover, small openings 16C₂ are formed at the arm 16C so as to correspond to the cutout portions 21A of the wafer support plate 21. Accordingly, the wafer transport unit 19 grips the pre-aligned semiconductor wafer W by the support portions 19A₁ of the three grip rods 19A, and the support portions 19A₁ of the three grip rods 19A pass through the cutout portions 21A of the wafer support plate 21 and the small openings 16C₂ when the semiconductor wafer W is transported onto the wafer support plate 21 from the sub-chuck 18A.

As shown in FIG. 4, protrusions 21B having openings 21B₁ through which the pins 19B₁ of the two positioning rods 19B of the wafer transport unit 19 are inserted are formed at the outer periphery of the wafer supporting plate 21 spaced at an interval of about 180° in a circumferential direction. One of the openings 21B₁ is formed in a circular shape having a diameter slightly larger than that of the pins, and the other opening (not shown) is formed in a narrow hole shape extending in a diametrical direction of the wafer supporting plate 21.

As shown in FIG. 6, an alignment unit 22 is provided in the alignment chamber 15. As shown in the same drawing, the alignment unit 22 includes: a moving body 22A, provided on a bottom surface (not shown) of the alignment chamber 15, moving in a horizontal direction and a vertical direction; an annular positioning member 22B, fixed on the bottom surface of the alignment chamber 15, surrounding the moving body 22A, for positioning the arm 16C to a predetermined location; a first and a second camera 22C₁ and 22C₂ for aligning the semiconductor wafer W through the wafer supporting plate 21 mounted on the upper arm 16C of the second wafer transfer unit 16 in cooperation with the moving body 22A; and a bridge 22D to which the first and the second camera 22C₁ and 22C₂ are fixed. The first and the second camera 22C₁ and 22C₂ capture an image of the top surface of the semiconductor wafer W at each focal position (alignment height). The first camera 22C₁ is disposed at the center of XY coordinates (the origin of XY coordinates) in the alignment chamber 15 to capture an image of the center (not shown) of the semiconductor wafer, and the second camera 22C₂ is disposed on the coordinate axis of the XY coordinates to capture an image of a target mark (not shown) of the peripheral portion of the semiconductor wafer W. Further, the first and the second camera 22C₁ and 22C₂ capture the image of the center and the target mark of the semiconductor wafer W, respectively. The control unit obtains a line connecting the center and the target mark of the semiconductor wafer W based on the position information thereof to obtain an inclination of the line with respect to the coordinate axis. Further, the control unit corrects the misalignment of the electrodes of the semiconductor wafer W corresponding to the probes of the pre-registered probe card.

As shown in FIG. 6, the positioning member 22B is formed as an annular plate-shaped member having an inner diameter larger than an outer diameter of the moving body 22A, and a plurality of (e.g., three) protrusions 22B₁ is formed on the top surface thereof spaced apart from each other at a predetermined interval in the circumferential direction. The protrusions 22B₁ are disposed on the circumference about a center axis of the first camera 22C₁ and respective XY coordinates thereof are previously set at an equal distance from the origin of the XY coordinates. Further, XY coordinates of the semiconductor wafer W which correspond to XY coordinates of the ends of the needles of the probes of the probe card in the test chamber 51 are set to XY coordinates in the alignment chamber 15. In other words, the XY coordinates in the alignment chamber are set to be the same as those in the test chamber 51.

Moreover, recesses 16C₃ that are fitted to the protrusions 22B₁ of the positioning member 22B are formed at the bottom surface of the upper arm 16C. The upper arm 16C enters the alignment chamber 15 and seats on the positioning member 22B after fitting the recesses 16C₃ to the protrusions 22B₁ of the positioning member 22B. The moving body 22A is movable inside the opening 16C₁ in the XY direction and can pass through the opening 16C₁ of the upper arm 16C.

The moving body 22A is positioned close to the wafer supporting body 21 below the central portion of the wafer supporting body 21. The moving body 22A is raised and brought into contact with the wafer supporting body 21 while passing through the opening 16C₁ of the upper arm 16C so as to lift the wafer supporting plate 21 from the upper arm 16C to the alignment height. Further, the moving body 22A is moved in the XY directions within the range between the opening 16C₁ of the upper arm 16C and the alignment height to align the semiconductor wafer W in cooperation with the first and the second camera 22C₁ and 22C₂. The moving body 22A returns the aligned semiconductor wafer W onto the upper arm 16C together with the wafer supporting plate 21 while being returned to the original position. The aligned semiconductor wafer W is unloaded from the alignment chamber 15 together with the wafer supporting body 21 by the upper arm 16C and transferred to the test chamber 51.

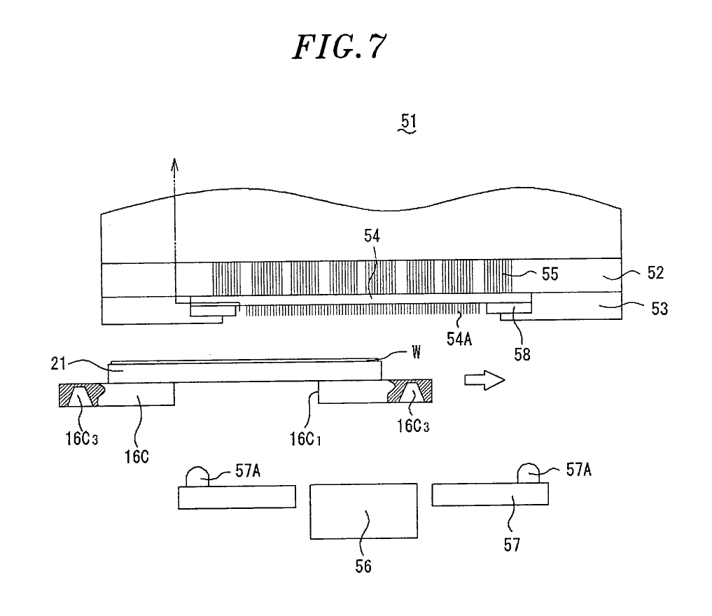

A plurality of (five in the present embodiment) test chambers 51 is arranged along the test area 50, and the electrical characteristics of the aligned semiconductor wafer W transferred together with the wafer supporting body 21 by the second wafer transfer unit 16 are tested in the test chamber 51. Further, the test chambers 51 at each arrangement position in the test area 50 are stacked vertically. The test chambers 51 of the respective stories have the same structure. Therefore, hereinafter, one test chamber 51 will be described as an example with reference to FIG. 7.

As shown in FIG. 7, the test chamber 51 includes: a probe card 54 fixed to a head plate 52 via a circular ring-shaped fixing ring 53; a plurality of pogo pin blocks 55 supported by the head plate 52 to connect the probe card 54 to a tester (not shown); an elevation body 56 for raising the wafer supporting body 21 from the upper arm 16C of the second wafer transfer unit 16 together with the semiconductor wafer W; and a ring-shaped positioning member 57, surrounding the elevation body 56, for positioning the upper arm 16C. A ring-shaped sealing member 58 for adsorbing a wafer (hereinafter, simple referred to as ‘sealing member’) having a predetermined width is formed at the bottom surface of the outer peripheral portion of the probe card 54 so as to surround the probes 54A, and the outer peripheral portion of the probe card 54 is elastically supported by the head plate 52 and the fixing ring 53 via the sealing member 58 formed at the bottom surface thereof.

An opening of a gas exhaust passage (not shown) positioned between the inner peripheral surface of the sealing member 58 and the probes 54A is formed at the outer peripheral portion of the probe card 54. A gas exhaust unit such as a vacuum pump or the like is connected to the gas exhaust passage, and air is exhausted from the outer peripheral portion of the probe card 54 via the gas exhaust passage as indicated by arrows in FIG. 7.

As shown in FIG. 7, a plurality of protrusions 57A fitted to the recesses 16C₃ of the upper arm 16C that enters the test chamber 51 is formed on the top surface of the positioning member 57 separated apart from each other at a regular interval in a circumferential direction. The protrusions 57A are located at positions of the same XY coordinates as those of the protrusion 22B₁ formed at the positioning member 22B in the alignment chamber 15. In other words, the XY coordinates in the test chamber 51 and the XY coordinates in the alignment chamber 15 are in a mirror image relationship, and the upper arm 16C seats on the positioning member 57 after determining the position thereof. When the semiconductor wafer W on the wafer supporting table 21 aligned in the alignment chamber 15 is lifted by the elevation body 56, the electrodes of the semiconductor wafer W is reliably brought into contact with the probes 54A of the probe card 54. Here, the configurations of the elevation body 56 and the positioning member 57 are substantially the same as those in the alignment chamber 15.

The elevation body 56 lifts the wafer supporting body 21 from the upper arm 16C supported by the protrusions 57A of the positioning member 57 in a vertical direction toward the probe card 54, and the circumferential portion of the semiconductor wafer W is brought into contact with the sealing member 21, thereby forming a sealed space. Here, the vacuum pump vacuum-exhausts the sealed space through the gas exhaust passage, so that the semiconductor wafer W is vacuum-adsorbed to the sealing member 21 and the electrodes of the semiconductor wafer W are brought into contact with the probes 54A of the probe card 54. The elevation body 56 leaves the vacuum-adsorbed semiconductor wafer W at the probe card 54 side and is lowered to separate the wafer supporting body 21 from the semiconductor wafer W and return the wafer supporting body 21 to the upper arm 16C. The upper arm 16C unloads the returned wafer supporting body 21 from the test chamber 51, and the elevation body 56 is lifted again to allow the semiconductor wafer W and the probes to be in pressure-contact, thereby testing the semiconductor wafer W. After the test, the tested semiconductor wafer W is transferred from the test chamber 51 to the buffer chamber 20 in the pre-aligned chamber 12 with the lower arm 16D of the second wafer transfer unit 16. Then, the tested semiconductor wafer W in the buffer chamber 20 is transferred from the buffer chamber 20 to the original location in the housing F in the wafer compartment 11 with the first wafer transfer unit 13.

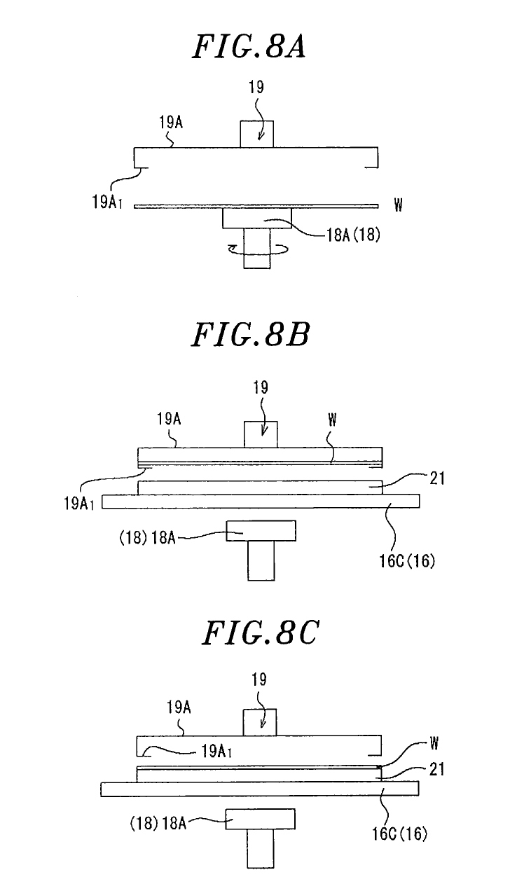

Hereinafter, the operation will be described. First, the housing F such as a FOUP or the like is mounted on each wafer compartment 11 of the wafer transfer device 10. In order to test the semiconductor wafers W, the first wafer transfer unit 13 is driven in the first wafer transfer chamber 14 to unload semiconductor wafers W one at a time from the housing F by using the arm 13C and transfer the semiconductor wafer W to the pre-alignment unit 18 in the pre-alignment chamber 12, as shown in FIG. 8A. Then, the semiconductor wafer W is pre-aligned therein. Thereafter, the wafer transport unit 19 is driven to grip and lift the semiconductor wafer W by using the three grip rods 19A, as shown in FIG. 8B. At this time, the second wafer transfer unit 16 is driven into the second wafer transfer chamber 17, and the upper arm 16C moves to the portion between the pre-alignment unit 18 and the wafer transport unit 19 while adsorbing the wafer supporting body 21. Then, the upper arm 16C is stopped at the position where the center of the semiconductor wafer W coincides with the center of the wafer supporting body 21.

Then, the three grip rods 19A of the wafer transport unit 19 are lowered by the arm 19D, and the support portions 19A₁ of the three grip rods 19A pass through the cutout portions 21A of the wafer supporting body 21 and the small openings 16C₂ of the upper arm 16C. Then, the semiconductor wafer W is mounted on the wafer supporting body 21. The three grip rods 19A are extended within the small openings 16C₂ of the upper arm 16C to separate the semiconductor wafer W therefrom. Thereafter, as shown in FIG. 8C, the three grip rods 19A are lifted with the arm 19D and returned to the original positions. When the semiconductor wafer W is transported to the second wafer transfer unit 16, the upper arm 16C is unloaded from the pre-alignment chamber 14 and the lower arm 16D is moved to the position facing the alignment chamber 15.

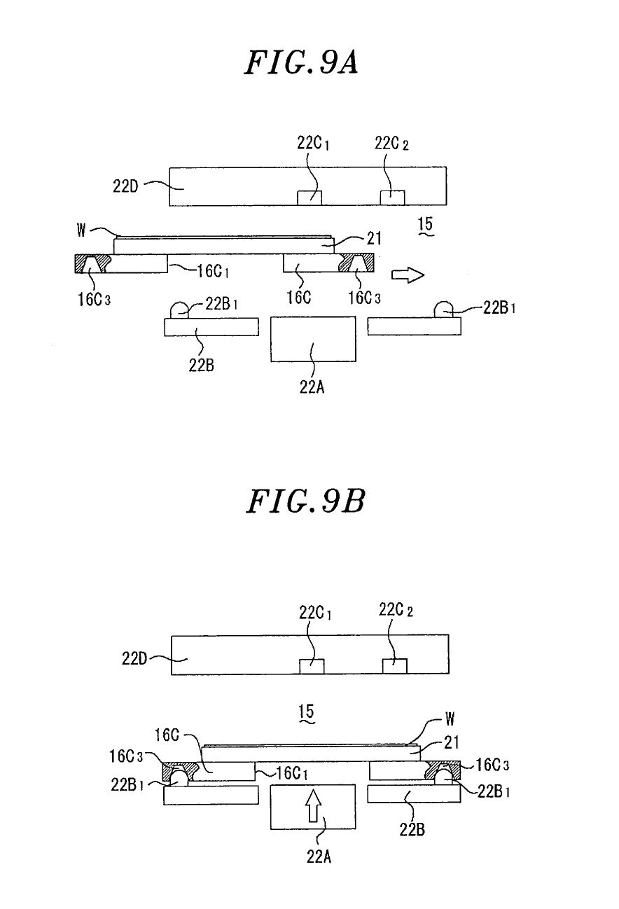

As shown in FIG. 9A, when the upper arm 16C of the second wafer transfer unit 16 reaches the portion above the positioning member 22B in the alignment chamber 15 and is lowered, the recesses 16C₃ of the upper arm 16C are fitted to the protrusion 22B₁ of the positioning member 22B, thereby automatically determining the position of the upper arm 16C in the alignment chamber 15. After the position is determined, the moving body 22A is lifted as indicated by an arrow line in FIG. 9B.

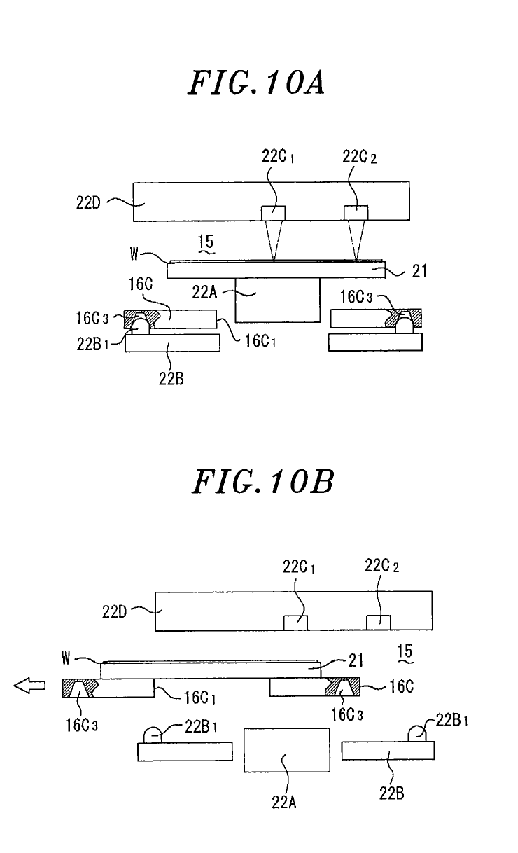

The moving body 22A is lifted and brought into contact with the wafer supporting plate 21. The moving body 22A is lifted to the alignment height as shown in FIG. 10A. At this position, the first and the second camera 22C₁ and 22C₂ are driven. The first camera 22C₁ captures an image of the semiconductor wafer W to recognize the center of the semiconductor wafer W. When the first camera 22C₁ cannot recognize the center of the semiconductor wafer W, the first camera 22C₁ searches the center of the semiconductor wafer W while moving in the XY directions within the range of the opening 16C₁ of the upper arm 16C to thereby recognize the center of the semiconductor wafer W. Next, the second camera 22C₂ captures an image of a target on the circumferential portion of the semiconductor wafer W to recognize a deviation in the θ direction of the semiconductor wafer W from the line connecting the center and the target and the coordinate axis. When the second camera 22C₂ recognizes the deviation of the semiconductor wafer W, the moving body 22A is rotated in the θ direction to correct the deviation of the semiconductor wafer W. Then, the first camera 22C₁ checks the center of the semiconductor wafer W again. After such process, the alignment of the semiconductor wafer W is completed.

After the alignment, the moving body 22A is lowered to the original position, and the wafer supporting plate 21 is mounted on the upper arm 16C together with the aligned semiconductor wafer W. Next, the aligned semiconductor wafer W is transferred together with the wafer supporting body 21 from the alignment chamber 15 to the predetermined test chamber 51 with the upper arm 16C, as indicated by an arrow in FIG. 10B.

As shown in FIG. 7, the upper arm 16C of the second wafer transfer unit 16 enters the test chamber 51. In the test chamber, the XY coordinates aligned in the alignment chamber 15 are reproduced by the positioning member 57. When the elevation body 56 is lifted to raise the wafer supporting body 21 in a vertical direction, the outer circumferential portion of the semiconductor wafer W comes into elastic contact with the sealing member 58 and the electrodes of the semiconductor wafer W are brought into contact with the probes 54A of the probe card 54 collectively. Accordingly, a sealed space is formed between the probe card 54 and the semiconductor wafer W. At this time, the sealed space is depressurized by the gas exhaust unit, and the semiconductor wafer W adheres to the sealing member 58. In that state, the elevation body 56 is lowered while holding the wafer supporting body 21 and transfers the wafer supporting body 21 onto the upper arm 16C. Then, the upper arm 16C is unloaded from the test chamber 51 and the elevation body 56 is lifted again to press the semiconductor wafer W toward the probe card 54. Subsequently, the electrodes of the semiconductor wafer W are brought into electrical contact with the probes 54A, thereby testing electrical characteristics of the semiconductor wafer W.

After the test, the vacuum adsorption by the gas exhaust unit is released, and the pressure in the sealed space is returned to a normal pressure. Then, the tested semiconductor wafer W is returned to the original position by the elevation body 56. At this time, the lower arm 16D receives the tested semiconductor wafer W from the elevation body 22 and is unloaded from the test chamber 51. Next, the tested semiconductor wafer W is accommodated in the buffer chamber 20. Thereafter, the first wafer transfer unit 13 is driven to return the tested semiconductor wafer W from the buffer chamber 20 to the housing F in the wafer compartment 11. Through such sequential operations, the test of the semiconductor wafer W is terminated. Other semiconductor wafers are tested in the same manner.

As described above, in accordance with the present embodiment, the wafer transfer device 10 is configured by arranging the wafer compartments 11, the pre-alignment chambers 12 and the alignment chambers 15 in a horizontal and a vertical direction, arranging the first wafer transfer chamber 14 having the first wafer transfer unit 13 along the wafer compartments 11 and the pre-alignment chamber 12 disposed in the vertical direction, and arranging the second wafer transfer chamber 17 having the second wafer transfer unit 16 along the pre-alignment chamber 12 and the alignment chamber 15 disposed the horizontal direction. Since the wafer transfer device 10 is shared by a plurality of test chambers 51, the footprint of the transfer device 10 can be considerably reduced and the cost of the test system can be greatly reduced compared to the conventional case.

Moreover, in accordance with the present embodiment, the wafer compartments 11, the pre-alignment chambers 12, the alignment chambers 15 and the second wafer transfer chambers 17 are horizontally symmetrically arranged with respect to the first wafer transfer chamber 14. Accordingly, such elements of the test system can be integrated more compactly, and the footprint can be further reduced. As a result, the cost can be further reduced.

The pre-alignment chamber 12 has the pre-alignment unit 18 for pre-aligning the semiconductor wafer W and the wafer transport unit 19 for transporting the semiconductor wafer W pre-aligned by the pre-alignment unit 18 to the second wafer transfer unit 16. Therefore, the pre-aligned semiconductor wafer W can be accurately and quickly transported from the pre-alignment unit 18 to the second wafer transfer unit 16.

The first wafer transfer unit 13 has the vertically movable base 13A and the arm 13B moving horizontally on the base 13A. The first wafer transfer unit 13 transfers the semiconductor wafer between the upper and the lower wafer compartments 11 and the pre-alignment chamber 12 through the arm 13B, so that it is possible to reduce the footprint of the first wafer transfer chamber 14, the wafer compartment 11 and the pre-alignment chamber 12.

The second wafer transfer unit 16 has the base 16A moving vertically and moving along the arrangement direction of the pre-alignment chamber 12 and the alignment chamber 15, and the upper and the lower arm 16C and 16D moving horizontally on the base 16A. With such configuration, the second wafer transfer unit 16 can effectively transfer the semiconductor wafer W among the pre-alignment chamber 12, the alignment chamber 15 and the test chamber 51.

The present invention is not limited to the above-described embodiment, and the design of the components may be modified if necessary.

While the invention has been shown and described with respect to the embodiments, it will be understood by those skilled in the art that various changes and modification may be made without departing from the scope of the invention as defined in the following claims.

What is claimed is:

1. A wafer transfer device for transferring a semiconductor wafer accommodated in a housing to a plurality of test chambers for testing electrical characteristics of the semiconductor wafer, the wafer transfer device comprising:
a wafer compartment for accommodating therein the housing;
a pre-alignment chamber, provided either above or below the wafer compartment, for pre-aligning the semiconductor wafer prior to the electrical characteristics test;
a first wafer transfer chamber, provided in a vertical direction along the wafer compartment and the pre-alignment chamber, for transferring the semiconductor wafer from the wafer compartment to the pre-alignment chamber;
an alignment chamber for aligning the semiconductor wafer, the alignment chamber being provided adjacent to the pre-alignment chamber with the pre-alignment chamber disposed between the alignment chamber and the first wafer transfer chamber;
a second wafer transfer chamber, disposed along an arrangement direction of the first wafer transfer chamber, the pre-alignment chamber and the alignment chamber, for transferring the semiconductor wafer among the pre-alignment chamber, the alignment chamber and the test chambers.

2. The wafer transfer device of claim 1, further comprising additional wafer compartment, additional pre-alignment chamber, and additional alignment chamber,
wherein the wafer compartments, the pre-alignment chambers, the alignment chambers, and the second wafer transfer chamber are horizontally symmetrically arranged with respect to the first wafer transfer chamber.

3. The wafer transfer device of claim 1, wherein the first wafer transfer chamber has a first wafer transfer unit for transferring the semiconductor wafer from the wafer compartment to the pre-alignment chamber.

4. The wafer transfer device of claim 1, wherein the pre-alignment chamber has a pre-alignment unit for pre-aligning the semiconductor wafer.

5. The wafer transfer device of claim 4, wherein the second wafer transfer chamber has a second wafer transfer unit for transferring the semiconductor wafer among the pre-alignment chamber, the alignment chamber and the test chambers.

6. The wafer transfer device of claim 5, wherein the pre-alignment chamber has a wafer transport unit for transporting the semiconductor wafer pre-aligned by the pre-alignment unit to the second wafer transfer unit.

7. The wafer transfer device of claim 5, wherein the second wafer transfer unit has a supporting plate for supporting the semiconductor wafer to transfer the semiconductor wafer.
